(19) United States
(12) Patent Application Publication
(10) Pub. No.: US 2024/0296990 A1
(43) Pub. Date: Sep. 5, 2024

(54) INTEGRATED CIRCUIT TRANSFORMER WITH CONCENTRIC WINDINGS AND MAGNETICALLY ACTIVE MATERIAL

(71) Applicant: Infineon Technologies Austria AG, Villach (AT)

(72) Inventors: Wolfgang FRANK, Augsburg (DE); Annett WINZER, Dresden (DE)

(21) Appl. No.: 18/177,437

(22) Filed: Mar. 2, 2023

(51) Int. Cl. H01F 27/28; H01F 27/29

(52) U.S. Cl. CPC H01F 27/2804; H01F 27/292; H01F 2027/2809; H01L 23/5227

(57) ABSTRACT

A multi-voltage domain device includes a circuit substrate comprising a first region comprising first circuitry, a second region comprising second circuitry, and an isolation region that electrically isolates the first region and the second region; a stack insulator layer arranged on the circuit substrate; a first coil arranged in the stack insulator layer and electrically coupled to the first circuitry; a second coil arranged in the stack insulator layer and electrically coupled to the second circuitry and magnetically coupled to the first coil; and a field concentrating structure arranged on the circuit substrate. The field concentrating structure is configured to attract a first magnetic field produced by the first coil such that the first magnetic field is concentrated about the first coil, and attract a second magnetic field produced by the second coil such that the second magnetic field is concentrated about the second coil.

### BACKGROUND

A high voltage (HV) gate driver circuit may include a low voltage (LV) gate driver used to drive a low-side transistor switch and an HV gate driver used to drive a high-side transistor switch. The LV gate driver is arranged in a low voltage domain, whereas the HV gate driver is arranged in a high voltage domain. In practice, the gate driver also includes a termination region that isolates the high voltage domain from the low voltage domain, and may be referred to as an isolation termination region. Thus, the isolation termination region provides a high voltage isolation barrier between the two voltage domains such that the two voltage domains remain electrically isolated from each other.

### SUMMARY

A multi-voltage domain device includes a circuit substrate comprising a first main surface and a second main surface arranged opposite to the first main surface. The circuit substrate comprises: a first region comprising first circuitry that operates in a first voltage domain; a second region comprising second circuitry that operates in a second voltage domain different from the first voltage domain; and an isolation region that electrically isolates the first region and the second region in a lateral direction that extends parallel to the first and the second main surfaces. The multi-voltage domain device further includes a layer stack arranged on the first main surface of the circuit substrate, the layer stack comprising a plurality of sub-insulator layers that form a stack insulator layer, a first coil arranged in the stack insulator layer, and a second coil arranged in the stack insulator layer and laterally separated from the first coil in the lateral direction by the stack insulator layer, wherein the first coil and the second coil are magnetically coupled to each other in the lateral direction, wherein the first coil is electrically coupled to the first circuitry and is isolated from the second region, and wherein the second coil is electrically coupled to the second circuitry and is isolated from the first region. The multi-voltage domain device further includes a field concentrating structure arranged on the first main surface, wherein the field concentrating structure is configured to attract a first magnetic field produced by the first coil such that the first magnetic field is concentrated about the first coil, and attract a second magnetic field produced by the second coil such that the second magnetic field is concentrated about the second coil.

### BRIEF DESCRIPTION OF THE DRAWINGS

Implementations are described herein making reference to the appended drawings.

FIG. 1 illustrates a top view of a lateral transformer according to one or more implementations.

FIG. 2A illustrates a cross-sectional view of a multi-voltage domain device according to one or more implementations.

FIG. 2B illustrates a top plan view, a middle plan view, and a bottom plan view of the multi-voltage domain device of FIG. 2A according to one or more implementations.

FIG. 2C illustrates a top plan view, a middle plan view, and a bottom plan view of the multi-voltage domain device of FIG. 2A according to one or more implementations.

FIG. 3 illustrates a cross-sectional view of a multi-voltage domain device according to one or more implementations.

FIG. 4 illustrates a cross-sectional view of a multi-voltage domain device according to one or more implementations.

FIG. 5A illustrates a cross-sectional view of a multi-voltage domain device according to one or more implementations.

FIG. 5B illustrates a cross-sectional view of a multi-voltage domain device according to one or more implementations.

FIG. 5C illustrates a cross-sectional view of a multi-voltage domain device according to one or more implementations.

FIG. 6 illustrates a cross-sectional view of a multi-voltage domain device according to one or more implementations.

FIG. 7A illustrates a cross-sectional view of a multi-voltage domain device according to one or more implementations.

FIG. 7B illustrates a top plan view, a middle plan view, and a bottom plan view of the multi-voltage domain device of FIG. 7A according to one or more implementations.

FIG. 7C illustrates a top plan view, a middle plan view, and a bottom plan view of the multi-voltage domain device of FIG. 7A according to one or more implementations.

FIG. 8 illustrates a middle plan view of a multi-voltage domain device according to one or more implementations.

FIG. 9 illustrates a cross-sectional view of a multi-voltage domain device according to one or more implementations.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view rather than in detail in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually exchangeable.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “top,” “bottom,” “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling, e.g., any connection or coupling without additional intervening elements, may also be implemented by an indirect connection or coupling, e.g., a connection or coupling with one or more additional intervening elements, or vice versa, as long as the general purpose of the connection or coupling, for example, to transmit a certain kind of signal or to transmit a certain kind of information, is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, an approximate signal value may practically have a signal value within 5% of the approximate signal value.

In the present disclosure, expressions including ordinal numbers, such as “first”, “second”, and/or the like, may modify various elements. However, such elements are not limited by the above expressions. For example, the above expressions do not limit the sequence and/or importance of the elements. The above expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

Multi-voltage domain devices, such as HV gate driver circuits, typically need a way to transmit signals between two electrically-isolated voltage domains. For example, in an HV gate driver circuit that includes an LV domain and an HV domain, an HV gate driver used to drive a high-side transistor switch may receive control signals and possibly other communication signals from circuitry located in the LV domain. In addition, faults that may occur in the HV domain may be communicated from circuitry located in the HV domain to the circuitry located in the LV domain. Accordingly, signals may be transmitted from the LV domain through a termination region to the HV domain, or vice versa.

The signals may be transferred over a vertical transformer. However, vertical transformers require an insulating material, such as an InterLayerDielectric (ILD), to isolate two vertically facing windings (e.g., coils) of the vertical transformer. The insulating material may be, for example, silicon oxide or imide, both of which have poor magnetic permeability μᵣ close to 1. Thus, a good coupling between the windings is not achieved. Moreover, it can be difficult, for such a vertical geometry on an integrated circuit (IC) level, to insert material with a high magnetic permeability between the windings to provide better coupling of the windings because an area between the windings is typically required for wire-bonding and does not allow the insertion of additional (magnetic) material or for a full encapsulation of the vertical transformer's geometry. As a result, magnetic fields produced by the windings are unguided and go astray (e.g., referred to as stray-fields). Thus, the windings of the vertical transformer are inefficient at energy transfer. In other words, due to the strong magnetic stray-fields of the unguided and unconcentrated magnetic field that couples the windings, the efficiency of energy transfer is poor and the vertical transformer is often limited by driving losses of a primary winding of the two windings.

Moreover, the ILD thickness dictates an isolation range. Increasing isolation requires changing the ILD and therefore changing the manufacturing process, including requiring a change in a certain minimum number of metal layers to guarantee enough ILD between the primary and the secondary coils and/or a special back-end-of-line (BEOL) process. These vertical arrangements to accommodate different levels of isolation are thus costly and inefficient from a manufacturing point of view and are not practical for HV gate driver processing.

Some implementations disclosed herein are directed to a multi-voltage domain device that uses a lateral transformer that uses a magnetic material with a high-magnetic permeability material for guided flow of the magnetic fields produced by windings (e.g., coils) as current flows through the windings. In some implementations, the lateral transformer may include a concentric arrangement of the windings including the use of the magnetic material for guided flow of the magnetic fields produced by the windings. A concentric configuration of the windings may simplify the introduction of the magnetic material in proximity to the windings.

The magnetic material may be used to form a field concentrating structure that is configured to attract a first magnetic field produced by a first winding (e.g., a first coil) of the transformer such that the first magnetic field is concentrated about the first winding, and attract a second magnetic field produced by a second winding (e.g., a second coil) such that the second magnetic field is concentrated about the second winding. As a result, an efficiency in energy transfer between the first winding and the second winding may be increased, with transfer losses being decreased.

In addition, according to a lateral arrangement or spacing between the windings, a thickness of an ILD need not be modified to achieve different levels of isolation, as is required in vertical transformers. Therefore, a manufacturing process does not need to be changed vertically to accommodate different isolation ranges for different multi-voltage domain devices and technologies. Instead, the lateral spacing will only call for a different lateral geometry within an already predefined layer as to where metal structures of the windings are laterally formed to accomplish different isolation ranges within the same manufacturing process.

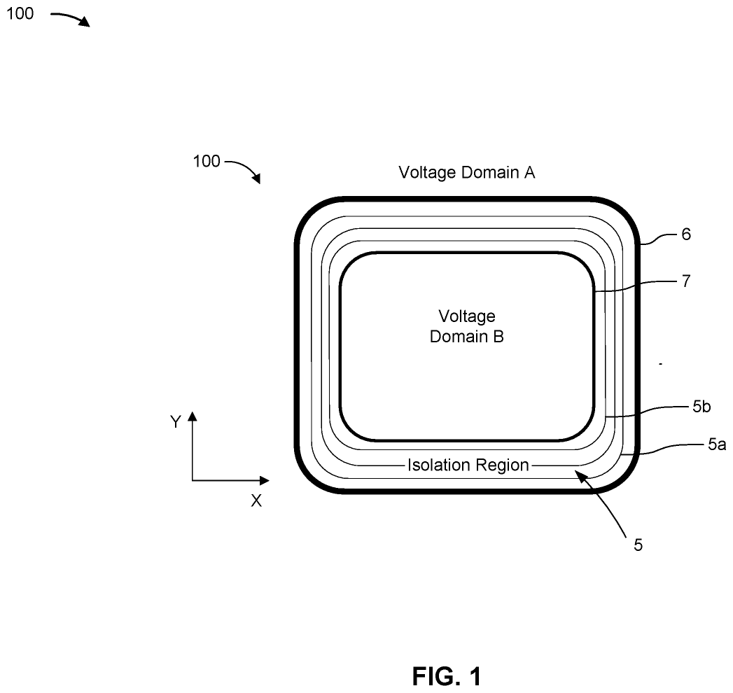

FIG. 1 illustrates a top view of a lateral transformer 100 of a multi-voltage domain device according to one or more implementations. The multi-voltage domain device may include a first voltage domain (e.g., voltage domain A) that is laterally isolated from a second voltage domain (e.g., voltage domain B) by an isolation region 5. For example, the voltage domain A and the voltage domain B may have different ground potentials. For example, the voltage domain A may be a low-voltage (LV) domain having a first ground potential (e.g., 0V) and the voltage domain B may be a high-voltage (HV) domain having a second ground potential (e.g., a floating ground potential) that is different from the first ground potential. For example, the second ground potential may be greater than the first ground potential and, as a result, the voltage domain B may be referred to as the higher voltage domain. In some implementations, the voltage domain A and the voltage domain B may have a same ground potential, but the voltage domain A and the voltage domain B may include circuitry that require galvanic isolation. A larger voltage difference between the first ground potential and the second ground potential may require a greater level of isolation in comparison to a level of isolation required for a smaller voltage difference between the first ground potential and the second ground potential.

In some implementations, the isolation region 5 may be associated with one or more deep trench isolation (DTI) barriers (e.g., vertical trenches at least partially filled with insulator material). For example, the isolation region 5 may include an outermost DTI barrier 5a and an innermost DTI barrier 5b. A quantity of DTI barriers and a lateral dimension of the isolation region 5 can be adjusted based on the desired level of isolation required to isolate the first voltage domain (e.g., voltage domain A) and the second voltage domain (e.g., voltage domain B).

The lateral transformer 100 includes two metal coils, a first coil 6 and a second coil 7, that may be formed on opposite lateral sides of the isolation region 5. The first coil 6 and the second coil 7 may be magnetically coupled to each other in a lateral direction. The first coil 6 may be electrically coupled to first circuitry of the voltage domain A and may be isolated from the voltage domain B. The second coil 7 may be electrically coupled to second circuitry of the voltage domain B and may be isolated from the voltage domain A. For example, the first coil 6 may be arranged at an edge region of voltage domain A and the second coil 7 may be arranged at an edge region of voltage domain B.

In some implementations, the first coil 6 may encircle an inner periphery of voltage domain A and the second coil 7 may encircle an outer periphery of voltage domain B such that their conductive lines are laterally facing each other. The isolation region 5 may laterally encircle voltage domain B to laterally separate the two voltage domains. In some implementations, coils 6 and 7 may be concentric coils. Furthermore, in some implementations, the isolation region 5 may be concentric with the coils 6 and 7.

As indicated above, FIG. 1 is provided as an example. Other examples may differ from what is described with regard to FIG. 1.

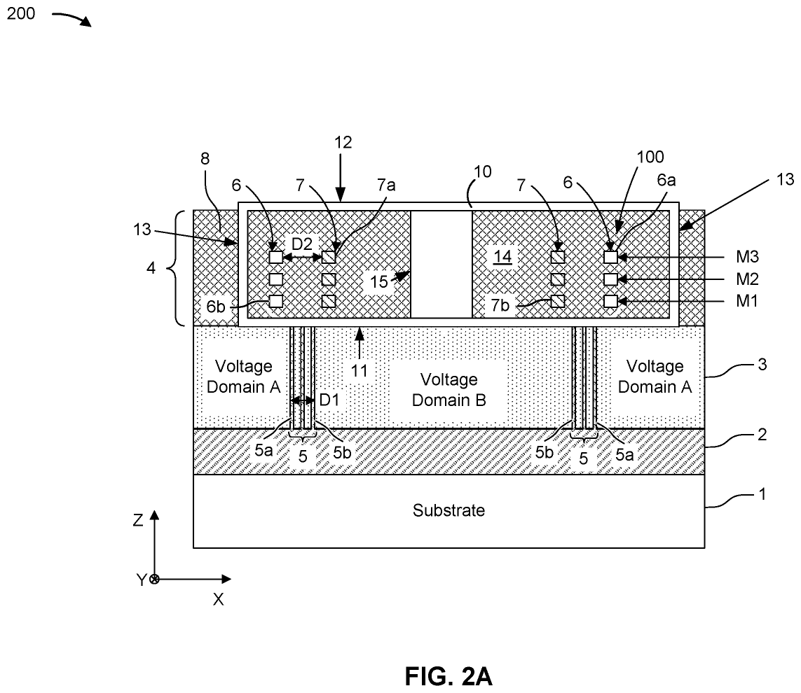

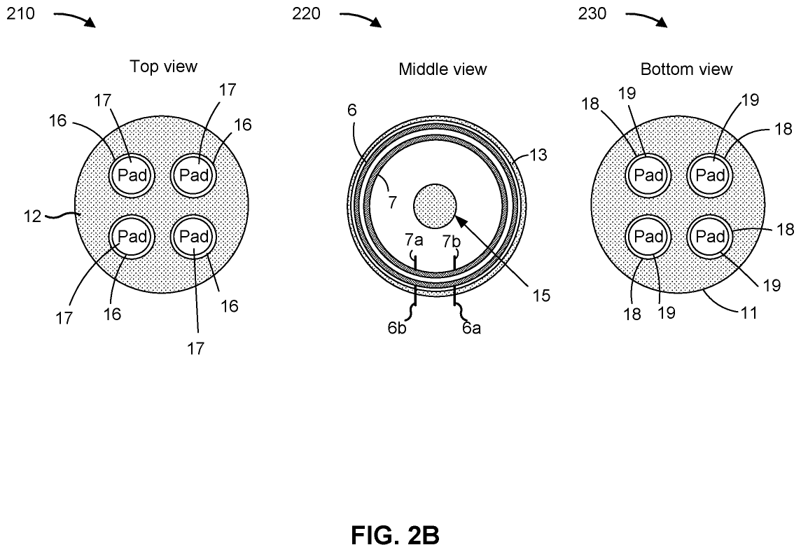

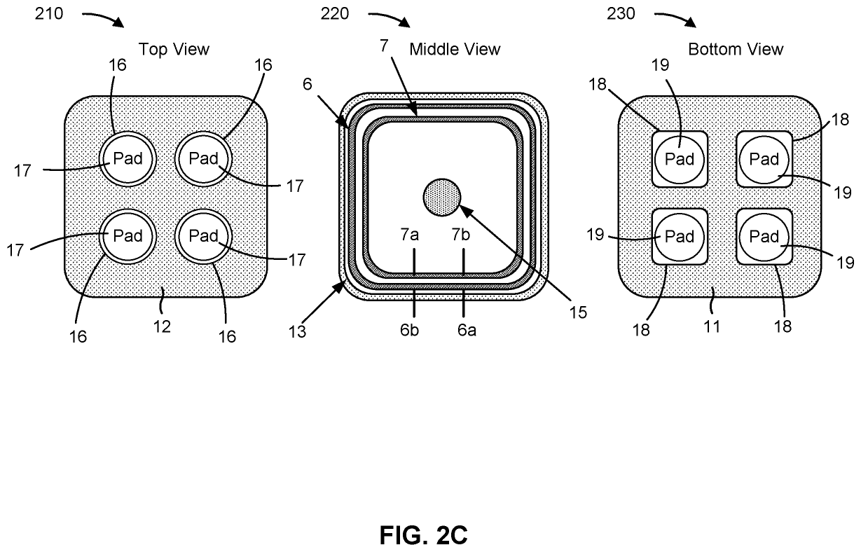

FIG. 2A illustrates a cross-sectional view of a multi-voltage domain device 200 according to one or more implementations. The multi-voltage domain device 200 may include the lateral transformer 100, including the first coil 6 and the second coil 7, as described in connection with FIG. 1.

In some implementations, the multi-voltage domain device 200 may include a semiconductor substrate 1, a buried oxide (BOX) layer 2, a circuit substrate 3 formed on the BOX layer 2, and a layer stack 4 formed on the circuit substrate 3. The circuit substrate 3 may be a semiconductor layer in which functional circuit components and devices are formed (e.g., integrated within). For example, the BOX layer 2 may be formed in a silicon-on-insulator (SOI) wafer that includes the semiconductor substrate 1 and the circuit substrate 3 (e.g., a semiconductor layer) arranged at opposite sides of the BOX layer 2. The BOX layer 2 may alternatively be referred to as a wafer insulator layer. It will be appreciated that other types of semiconductor substrate/insulator layer structures may also be used.

In some implementations, the circuit substrate 3 may be a printed circuit board (PCB) in which functional circuit components and devices are formed. In this case, the semiconductor substrate 1 and the BOX layer 2 may optionally not be provided, since the PCB is sturdy and isolating on its own, which may render the semiconductor substrate 1 and the BOX layer 2 as not needed.

The layer stack 4 may include metal layers (e.g., metal layers M1, M2, and M3) formed in a stack insulator layer 8, such as an oxide layer. For example, metal layers may be alternated with one or more insulator sub-layers in the vertical direction to form the layer stack 4.

Multiple metal layers, such as metal layers M1, M2, and M3, may be deposited within the layer stack 4 to form the coils 6 and 7 of the lateral transformer 100. The metal layers M1, M2, and M3 may be vertically separated (isolated) from each other in the z-direction by one or more sub-insulator layers of the stack insulator layer 8, with the exception that a conductive structure segment (e.g., a vertical metal segment or via) may be provided in the sub-insulator layer to connect two adjacent metal layers. The conductive structure segment may electrically couple the two adjacent metal layers together, thereby providing an electrical pathway between the two metal layers such that a continuous coil can be formed. Thus, the coils 6 and 7 may be formed from vertically overlapping metal layers. The minimum number of metal layers is one, while the total number of metal layers is limited only by manufacturing practicality.

Furthermore, as will be discussed in greater detail below, metal layers of different coil structures are laterally separated (isolated) from each other in the x-direction by the insulator material of the stack insulator layer 8.

In some implementations, the layer stack 4 may be a circuit substrate, such as a PCB, that includes alternating conductive layers and insulating layers. The coils 6 and 7 may be formed using conductive traces and conductive vias in the PCB. The layer stack 4, implemented as a PCB may be attached to one or more semiconductor chips in a back-end process (e.g., attached to a semiconductor chip formed by circuit substrate 3 or attached to a semiconductor chip formed by the semiconductor substrate 1, the BOX layer 2, and the circuit substrate 3). For example, the layer stack 4 may be attached to a semiconductor chip that includes circuit components arranged in two or more voltage domains. Alternatively, the layer stack 4 may be attached to multiple semiconductor chips, where each semiconductor chip may include a separate voltage domain.

In some implementations, the circuit substrate 3 and the layer stack 4 may be part of a same PCB. For example, the circuit substrate 3 may be composed of a first layer stack of the PCB that includes a first plurality of PCB layers (e.g., insulator layers and conductive layers) and the layer stack 4 may be composed of a second layer stack of the PCB that includes a second plurality of PCB layers (e.g., insulator layers and conductive layers), where the conductive layers are used to form the coils 6 and 7 and conductive traces between components. In this case, the isolation region 5 may be formed by the insulator layers of the first layer stack of the PCB and the coils 6 and 7 may be isolated from each other by insulator layers of the second layer stack of the PCB.

In some implementations, the circuit substrate 3 and the layer stack 4 may be part of separate PCBs that are coupled together, for example, by an adhesive or another fixing material or structure.

Each of the DTI barriers of the isolation region 5, including DTI barrier 5a and DTI barrier 5b, may extend vertically from an upper main surface of the circuit substrate 3 to the BOX layer 2 (e.g., to a lower main surface of the circuit substrate 3). Thus, each of the DTI barriers of the isolation region 5 may be a trench partially filled with the same or different insulating materials than the one used for the BOX layer 2 and is delimited by semiconductor material of the circuit substrate 3 that forms the sidewalls of the trench. DTI should be built in a manner to provide lateral isolation within the circuit substrate 3, practically defining the isolation region 5 within the circuit substrate 3. Therefore, the minimum number of DTIs may be one. A DTI barrier may be partially filled with an insulator material and/or polysilicon to fill the trench.

The lateral dimension D1 of the isolation region 5 is defined by the outer sidewall of the outermost DTI barrier 5a and an inner sidewall of the innermost DTI barrier 5b. The number of DTI barriers provided in the isolation region 5 and the lateral dimension of the isolation region 5 can be adjusted based on the desired level of isolation required to isolate the first voltage domain (e.g., voltage domain A) from the second voltage domain (e.g., voltage domain B).

The lateral transformer 100 is formed in the layer stack 4 (e.g., within the stack insulator layer 8) and includes the coils 6 and 7 formed by the metal layers M1, M2, and M3. The coils 6 and 7 may be formed on opposite lateral sides of the isolation region 5. Additionally, the coils 6 and 7 may be laterally separated (isolated) from each other in the x-direction by the insulator material of the stack insulator layer 8. Each metal layer of the first coil 6 and the second coil 7 may be conductively coupled to an adjacent metal layer by a metal via or other metal structure that is formed in the sub-insulator layers located between the two adjacent metal layers. Thus, metal layers M1 and M2 of the first coil 6 are conductively coupled together and metal layers M2 and M3 of the first coil 6 are conductively coupled together so that the first coil 6 is a continuous conductive structure, whereby the first coil 6 extends from terminal 6a to terminal 6b. As can be seen, the two terminals 6a and 6b of first coil 6 may be arranged diagonally across from each other and may each be coupled to a respective contact pad (not illustrated) and connected by the respective contact pad to the first circuitry of the voltage domain A. The metal line of the first coil 6 spirals vertically through the layer stack 4.

The terminals 6a and 6b have opposing potentials (e.g., Vp+ and Vp−) and are each coupled to an electrical contact, such as a bond pad or a metal line, located in the first voltage domain (e.g., voltage domain A). The electrical contacts may be coupled to respective terminals of a communication circuit located in voltage domain A that is configured to either excite the first coil 6 for data transmission, or receive (i.e., sample) a data transmission from the first coil 6. Alternatively, the terminals 6a and 6b may be coupled directly to the respective terminals of the communication circuit located in voltage domain A.

Similarly, metal layers M1 and M2 of the second coil 7 are conductively coupled together and metal layers M2 and M3 of second coil 7 are conductively coupled together so that the second coil 7 is a continuous conductive structure, whereby the second coil 7 extends from terminal 7a to terminal 7b. As can be seen, the two terminals 7a and 7b of second coil 7 may be arranged catty-corner to each other and may each be coupled to a respective contact pad (not illustrated) and connected by the respective contact pad to the second circuitry of the voltage domain B. The metal line of the second coil 7 spirals vertically through the layer stack 4.

The terminals 7a and 7b have opposing potentials (e.g., Vs+ and Vs−) and are each coupled to an electrical contact, such as a bond pad or a metal line, located in the second voltage domain (e.g., voltage domain B). The electrical contacts may be coupled to respective terminals of a communication circuit located in voltage domain B that is configured to either excite the second coil 7 for data transmission or receive (i.e., sample) a data transmission from the second coil 7. Alternatively, the terminals 7a and 7b may be coupled directly to the respective terminals of the communication circuit located in voltage domain B.

According to the lateral arrangement of the coils 6 and 7, the number of sub-insulator layers of the layer stack 4 defining the thickness of the ILD need not be modified to achieve different levels of isolation, as is required in vertical transformers. Therefore, the manufacturing process does not need to be changed vertically to accommodate different isolation ranges for different multi-voltage domain devices and technologies. Instead, the lateral spacing will only call for a different lateral geometry within an already predefined layer (e.g., the stack insulator layer 8) as to where the metal structures of the coils are laterally formed to accomplish different isolation ranges within the same manufacturing process. Furthermore, in the case of DTI based isolation, the lateral spacing may be directly defined by the DTI barrier region. Furthermore, a lateral oxide region defined by dimension D2 in the layer stack 4 may be used to isolate the signal transmission channel and does not expose HV terminals over a passivation/molding compound, as may be the case with vertical transformers or vertical capacitive coupled solutions.

The multi-voltage domain device 200 further includes a field concentrating structure 10 that may be configured to attract a first magnetic field produced by the first coil 6 such that the first magnetic field is concentrated about the first coil 6. Alternatively, or additionally, the field concentrating structure 10 may be configured to attract a second magnetic field produced by the second coil 7 such that the second magnetic field is concentrated about the second coil 7. The field concentrating structure 10 may be made of a magnetic material (e.g., ferrite material) configured to attract and guide magnetic fields produced by the first coil 6 and the second coil 7. The field concentrating structure 10 may also provide magnetic shielding for adjacent components.

In some implementations, the field concentrating structure 10 may be configured to guide the first magnetic field along a first magnetic field path, including through the field concentrating structure 10, and to guide the second magnetic field along a second magnetic field path, including through the field concentrating structure 10. Accordingly, the field concentrating structure 10 may reduce a quantity of the stray-fields produced by the first coil 6 and the second coil 7, which may lead to improved coupling of the first coil 6 and the second coil 7, and thus to an increased energy transfer efficiency between the first coil 6 and the second coil 7. In some implementations, the field concentrating structure 10 may prevent stray-fields from occurring.

In some implementations, the field concentrating structure 10 may be arranged on the upper main surface of the circuit substrate 3. For example, the field concentrating structure 10 may be at least partially formed in the layer stack 4. For example, the field concentrating structure 10 may be at least partially formed or integrated in the stack insulator layer 8. In addition, the field concentrating structure 10 may be electrically isolated from the first coil 6 and the second coil 7 by the stack insulator layer 8. Thus, the field concentrating structure 10 may also be electrically isolated from the first circuitry of the voltage domain A and from the second circuitry of the voltage domain B.

As shown in FIG. 2A, the field concentrating structure 10 encapsulates the first coil 6 and the second coil 7, which may provide a highest reduction in stray-fields and thus provide highest performance in efficiency with respect to energy transfer between the coils 6 and 7. The field concentrating structure 10 may include a bottom magnetic structure 11 (e.g., a bottom magnetic layer) arranged below the first coil 6 and the second coil 7, a top magnetic structure 12 (e.g., a top magnetic layer) arranged over the first coil 6 and the second coil 7, and a magnetic ring structure 13 that surrounds the first coil 6 and the second coil 7. For example, the magnetic ring structure 13 may encircle the first coil 6 and the second coil 7 and may be concentric with the first coil 6 and the second coil 7.

In some implementations, the bottom magnetic structure 11 may be arranged directly on the upper main surface of the circuit substrate 3. In some implementations, the bottom magnetic structure 11 may be arranged indirectly on the upper main surface of the circuit substrate 3 and may be vertically separated from the circuit substrate 3 by a portion of the stack insulator layer 8. That is, the bottom magnetic structure 11 may be arranged between the upper main surface and the coils 6 and 7. Thus, the bottom magnetic structure 11 may be part of the layer stack 4. The top magnetic structure 12 may be arranged on the stack insulator layer 8 or integrated within the stack insulator layer 8. Thus, the top magnetic structure 12 may be part of the layer stack 4 or may be arranged on top of the layer stack 4.

The magnetic ring structure 13 may extend vertically between the bottom magnetic structure 11 and the top magnetic structure 12 to define an internal volume 14 in which the first coil 6 and the second coil 7 are arranged. Thus, the magnetic ring structure 13 may be part of the layer stack 4. In some implementations, the magnetic ring structure 13 may extend partially between the bottom magnetic structure 11 and the top magnetic structure 12. For example, the magnetic ring structure 13 may be vertically separated from the bottom magnetic structure 11 and the top magnetic structure 12 by the stack insulator layer 8. Alternatively, the magnetic ring structure 13 may be mechanically coupled to a first one of the bottom magnetic structure 11 or the top magnetic structure 12 and may be vertically separated from a second one of the bottom magnetic structure 11 or the top magnetic structure 12 by the stack insulator layer 8. In some implementations, the magnetic ring structure 13 may extend fully between the bottom magnetic structure 11 and the top magnetic structure 12 such that the magnetic ring structure 13 may be mechanically coupled to the bottom magnetic structure 11 and the top magnetic structure 12.

Additionally, the field concentrating structure 10 may include a magnetic column 15 that is arranged within the internal volume 14. For example, magnetic column 15 may be arranged over the voltage domain B and may extend vertically between the bottom magnetic structure 11 and the top magnetic structure 12. Thus, the magnetic column 15 may be encircled by the first coil 6, the second coil 7, and the magnetic ring structure 13. The magnetic column 15 may extend partially between or fully between the bottom magnetic structure 11 and the top magnetic structure 12. Thus, the magnetic column 15 may be vertically separated from one or both of the bottom magnetic structure 11 and the top magnetic structure 12. In other words, the magnetic column 15 may be mechanically coupled to one or both of the bottom magnetic structure 11 and the top magnetic structure 12, or the magnetic column 15 may be vertically separated from both the bottom magnetic structure 11 and the top magnetic structure 12. The magnetic column 15 may increase a magnetic field concentration of the magnetic fields around their respective coils 6 and 7. As a result, the magnetic column 15 may enable smaller diameters to be used for the first coil 6 and the second coil 7 than would otherwise be practical.

The bottom magnetic structure 11, the top magnetic structure 12, the magnetic ring structure 13, and the magnetic column 15 may be magnetically coupled to each other in order to attract the magnetic fields produced by the coils 6 and 7 and guide the magnetic fields about their respective coils 6 and 7.

Thus, the field concentrating structure 10 may enable size reductions because a spacing between the coils 6 and 7 can be reduced. In addition, a driving circuit and rectification circuit of the lateral transformer 100 may be cheaper to be realized as a part of an IC. Thus, the field concentrating structure 10 may reduce system costs.

As indicated above, FIG. 2A is provided as an example. Other examples may differ from what is described with regard to FIG. 2A. The number and arrangement of devices and components shown in FIG. 2A are provided as an example. In practice, there may be additional devices or components, fewer devices or components, different devices or components, or differently arranged devices or components than those shown in FIG. 2A. For example, in some implementations, the bottom magnetic structure 11 may be absent. In some implementations, the top magnetic structure 12 may be absent. In some implementations, the magnetic ring structure 13 may be absent. In some implementations, the magnetic column 15 may be absent.

FIG. 2B illustrates a top plan view 210, a middle plan view 220, and a bottom plan view 230 of the multi-voltage domain device 200 according to one or more implementations. The top plan view 210 is taken through a top portion of the field concentrating structure 10, through the top magnetic structure 12 along the x-axis. The middle plan view 220 is taken through a middle portion of the field concentrating structure 10, through the magnetic ring structure 13 along the x-axis. The bottom plan view 230 is taken through a bottom portion of the field concentrating structure 10, through the bottom magnetic structure 11 along the x-axis.

As shown in the top plan view 210, the top magnetic structure 12 may have a disc shape that may be matched with a shape of the magnetic ring structure 13. The top magnetic structure 12 may have a plurality of openings 16 which may be used for forming electrical connections between the first circuitry of the voltage domain A and the terminals 6a and 6b of the first coil 6, and for forming electrical connections between the second circuitry of the voltage domain B and the terminals 7a and 7b of the second coil 7. For example, conductive interconnects may be formed through respective openings of the plurality of openings 16 to connect the first circuitry of the voltage domain A and the terminals 6a and 6b of the first coil 6. Similarly, conductive interconnects may be formed through second respective openings of the plurality of openings 16 to connect the second circuitry of the voltage domain B and the terminals 7a and 7b of the second coil 7.

In some implementations, a plurality of contact pads 17 may be respectively arranged in the plurality of openings 16 of the top magnetic structure 12. Each of the terminals 6a and 6b of the first coil 6 and the terminals 7a and 7b of the second coil 7 may be electrically coupled to the first circuitry or to the second circuitry by a respective contact pad of the plurality of contact pads 17.

Alternatively, as shown in the bottom plan view 230, the bottom magnetic structure 11, also having a disc shape, may have a plurality of openings 18 which may be used for forming electrical connections between the first circuitry of the voltage domain A and the terminals 6a and 6b of the first coil 6, and for forming electrical connections between the second circuitry of the voltage domain B and the terminals 7a and 7b of the second coil 7. For example, conductive interconnects may be formed through respective openings of the plurality of openings 18 to connect the first circuitry of the voltage domain A and the terminals 6a and 6b of the first coil 6. Similarly, conductive interconnects may be formed through second respective openings of the plurality of openings 18 to connect the second circuitry of the voltage domain B and the terminals 7a and 7b of the second coil 7.

In some implementations, a plurality of contact pads 19 may be respectively arranged in the plurality of openings 18 of the bottom magnetic structure 11. Each of the terminals 6a and 6b of the first coil 6 and the terminals 7a and 7b of the second coil 7 may be electrically coupled to the first circuitry or to the second circuitry by a respective contact pad of the plurality of contact pads 19.

As shown in the middle plan view 220, the magnetic ring structure 13 may be concentric with the first coil 6 and the second coil 7. In addition, the magnetic column 15 may be arranged at a center of the internal volume 14.

As indicated above, FIG. 2B is provided as an example. Other examples may differ from what is described with regard to FIG. 2B.

FIG. 2C illustrates the top plan view 210, the middle plan view 220, and the bottom plan view 230 of the multi-voltage domain device 200 according to one or more implementations. The multi-voltage domain device 200 shown in FIG. 2C is similar to the multi-voltage domain device 200 described in connection with FIG. 2B, with the exception that the first coil 6, the second coil 7, the bottom magnetic structure 11, the top magnetic structure 12, and the magnetic ring structure 13 have a rectangular shape.

As indicated above, FIG. 2C is provided as an example. Other examples may differ from what is described with regard to FIG. 2C.

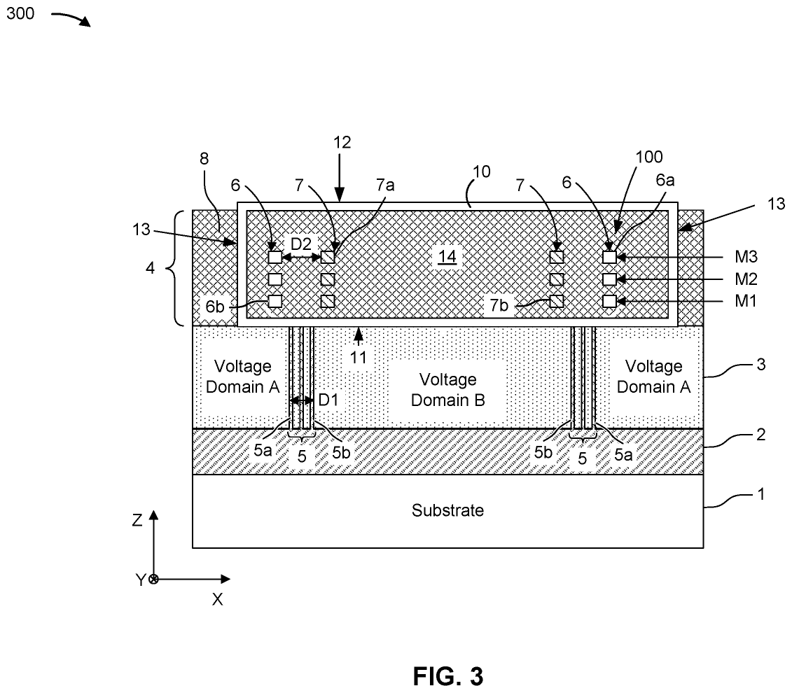

FIG. 3 illustrates a cross-sectional view of a multi-voltage domain device 300 according to one or more implementations. The multi-voltage domain device 300 is similar to the multi-voltage domain device 200 described in connection with FIGS. 2A and 2B, with the exception that the field concentrating structure 10 does not include the magnetic column 15.

As indicated above, FIG. 3 is provided as an example. Other examples may differ from what is described with regard to FIG. 3.

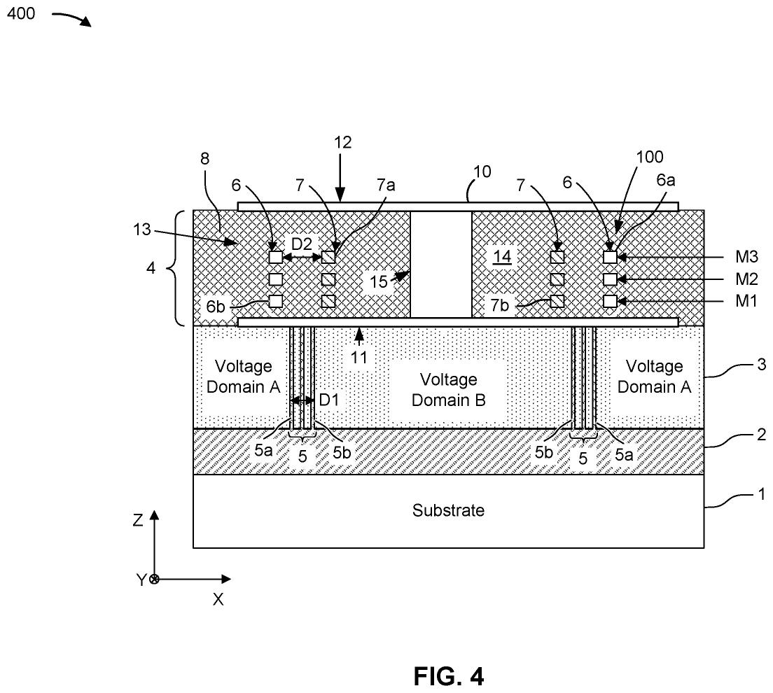

FIG. 4 illustrates a cross-sectional view of a multi-voltage domain device 400 according to one or more implementations. The multi-voltage domain device 400 is similar to the multi-voltage domain device 200 described in connection with FIGS. 2A and 2B, with the exception that the field concentrating structure 10 does not include the magnetic ring structure 13. This configuration may enable conductive interconnects to be formed through respective side regions of the magnetic ring structure 13 for connecting the terminals 6a and 6b of the first coil 6 to the first circuitry of the voltage domain A. The openings 16 or 18 may still be used for connecting the terminals 7a and 7b of the second coil 7 to the second circuitry of the voltage domain B.

As indicated above, FIG. 4 is provided as an example. Other examples may differ from what is described with regard to FIG. 4.

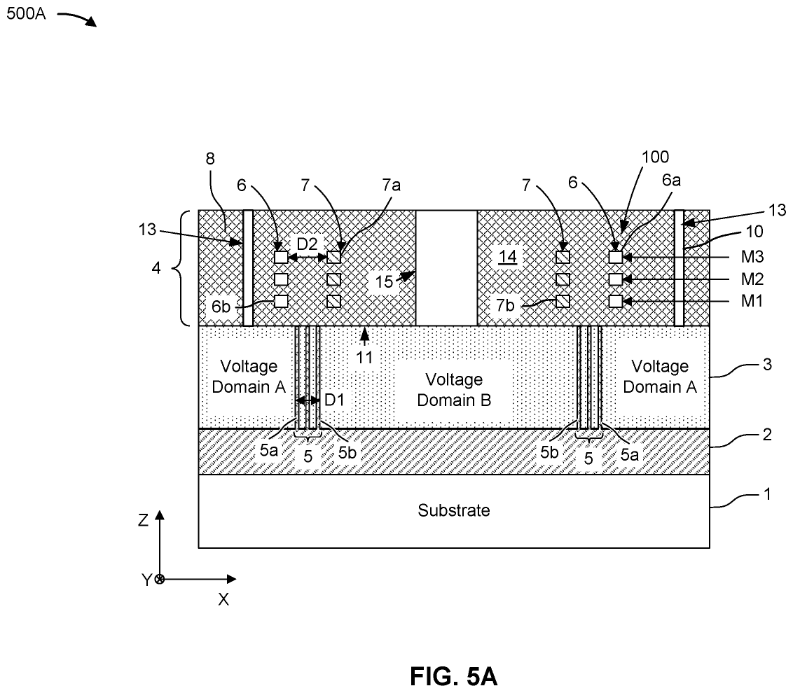

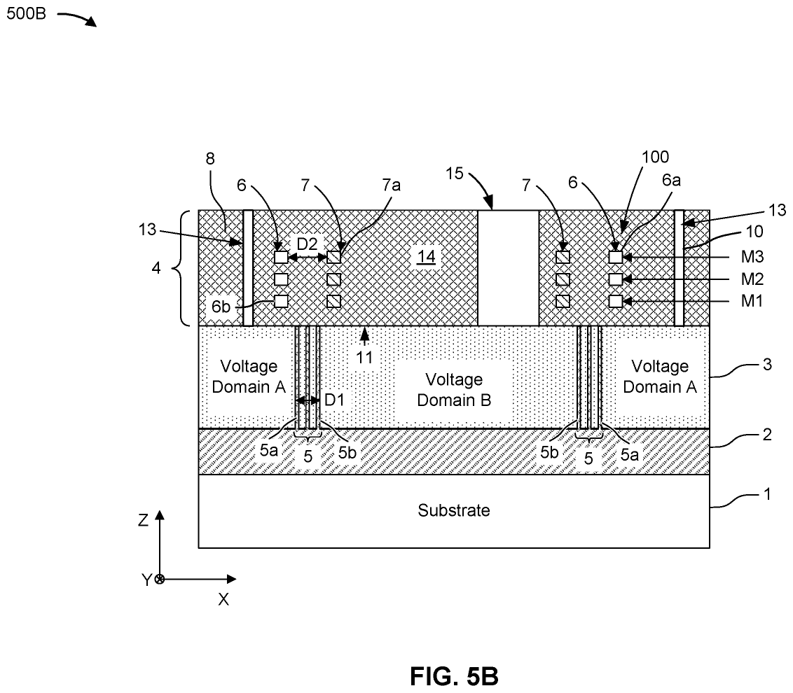

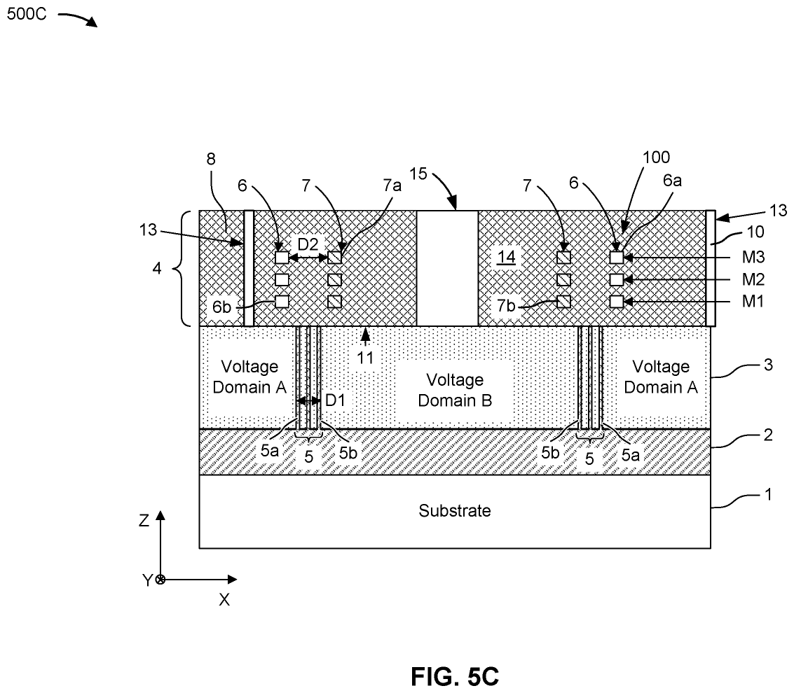

FIG. 5A illustrates a cross-sectional view of a multi-voltage domain device 500A according to one or more implementations. The multi-voltage domain device 500A is similar to the multi-voltage domain device 200 described in connection with FIGS. 2A and 2B, with the exception that the field concentrating structure 10 does not include the bottom magnetic structure 11 and the top magnetic structure 12.

This configuration may enable conductive interconnects to be formed vertically between the terminals 6a and 6b of the first coil 6 and the first circuitry of the voltage domain A, and vertically between the terminals 7a and 7b of the second coil 7 and the second circuitry of the voltage domain B, through a region where bottom magnetic structure 11 is no longer present.

Additionally, or alternatively, contact pads 17 or 19 may be provided to provide the electrical connections between the terminals 6a and 6b of the first coil 6 and the first circuitry of the voltage domain A and between the terminals 7a and 7b of the second coil 7 and the second circuitry of the voltage domain B.

As indicated above, FIG. 5A is provided as an example. Other examples may differ from what is described with regard to FIG. 5A.

FIG. 5B illustrates a cross-sectional view of a multi-voltage domain device 500B according to one or more implementations. The multi-voltage domain device 500B is similar to the multi-voltage domain device 500A described in connection with FIG. 5A, with the exception that the magnetic column 15 is asymmetrically arranged within the internal volume 14. In other words, the magnetic column 15 is laterally offset from a geometric center of the coils 6 and 7.

As indicated above, FIG. 5B is provided as an example. Other examples may differ from what is described with regard to FIG. 5B.

FIG. 5C illustrates a cross-sectional view of a multi-voltage domain device 500C according to one or more implementations. The multi-voltage domain device 500C is similar to the multi-voltage domain device 500A described in connection with FIG. 5A, with the exception that the magnetic ring structure 13 has an asymmetrical or eccentric shape. For example, magnetic ring structure 13 may have an oval or elliptical shape.

As indicated above, FIG. 5C is provided as an example. Other examples may differ from what is described with regard to FIG. 5C.

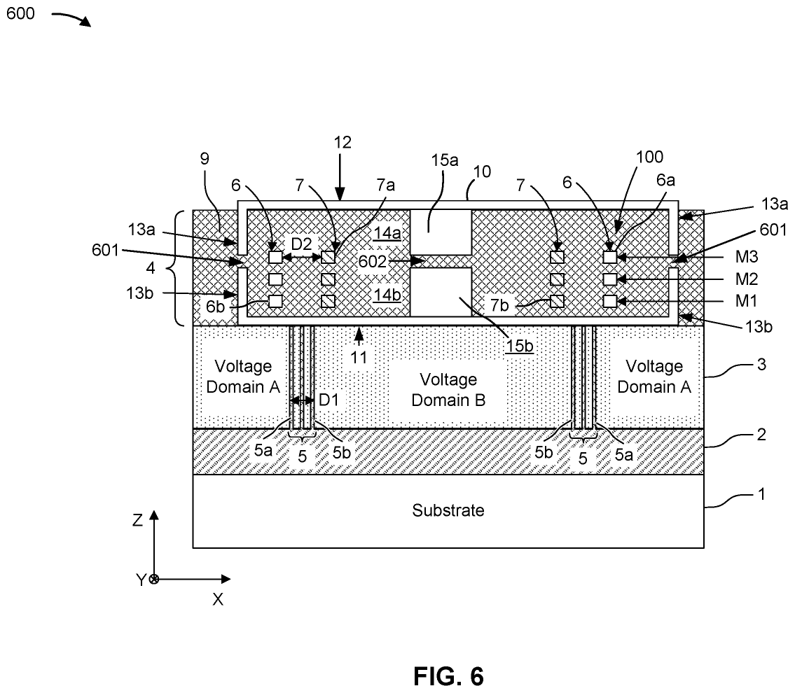

FIG. 6 illustrates a cross-sectional view of a multi-voltage domain device 600 according to one or more implementations. The multi-voltage domain device 600 is similar to the multi-voltage domain device 200 described in connection with FIGS. 2A and 2B, with the exception that the field concentrating structure 10 includes two magnetic ring structures 13a and 13b separated by a vertical gap 601 instead of a single magnetic ring structure (e.g., the magnetic ring structure 13), and the field concentrating structure 10 includes two magnetic columns 15a and 15b separated by a vertical gap 602 instead of a single magnetic column (e.g., the magnetic column 15). In other words, the two magnetic ring structures 13a and 13b may vertically overlap with each other and the two magnetic columns 15a and 15b may vertically overlap with each other.

The magnetic ring structure 13a and the magnetic ring structure 13b may both be concentric with the first coil 6 and the second coil 7. The magnetic ring structure 13a may define a first internal volume 14a in which the first coil 6 and the second coil 7 are arranged. Additionally, the magnetic ring structure 13b may define a second internal volume 14b in which the first coil 6 and the second coil 7 are arranged.

In addition, the magnetic ring structure 13a and the magnetic ring structure 13b may be formed in different vertical portions of the layer stack 4. For example, the magnetic ring structure 13a may be arranged in a first sub-stack of the layer stack 4 and the magnetic ring structure 13b may be arranged in a second sub-stack of the layer stack 4. Moreover, the magnetic ring structure 13a and the magnetic ring structure 13b may be separated by at least one sub-insulator layer of the layer stack 4 arranged in the vertical gap 601.

The vertical gap 601 may be large enough to permit conductive interconnects to be formed in the sub-insulator layers within the vertical gap. The conductive interconnects may extend through the vertical gap 601 and may be used to connect the terminals 6a and 6b to the first circuitry of the voltage domain A and/or to connect the terminals 7a and 7b to the second circuitry of the voltage domain B.

The magnetic columns 15a and 15b may be arranged in the stack insulator layer 8 over the voltage domain B. Both the magnetic columns 15a and 15b may extend vertically within the layer stack 4 and may be surrounded by the first coil 6 and the second coil 7. In addition, the magnetic ring structure 13a and the magnetic ring structure 13b may be formed in different vertical portions of the layer stack 4. For example, the magnetic column 15a may be arranged in a third sub-stack of the layer stack 4 and the magnetic column 15b may be arranged in a fourth sub-stack of the layer stack 4. Moreover, the magnetic column 15a and the magnetic column 15b may be separated by at least one sub-insulator layer of the layer stack 4 arranged in the vertical gap 602.

As indicated above, FIG. 6 is provided as an example. Other examples may differ from what is described with regard to FIG. 6.

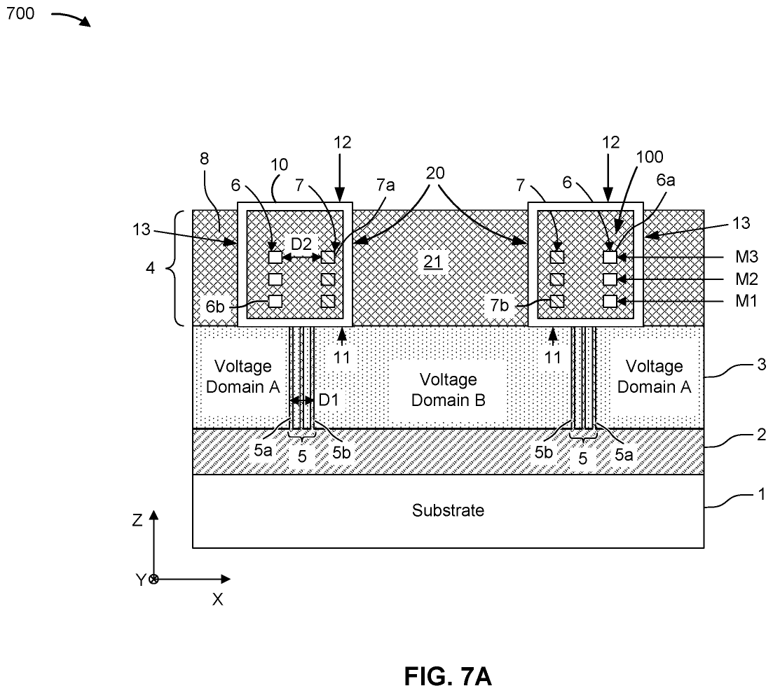

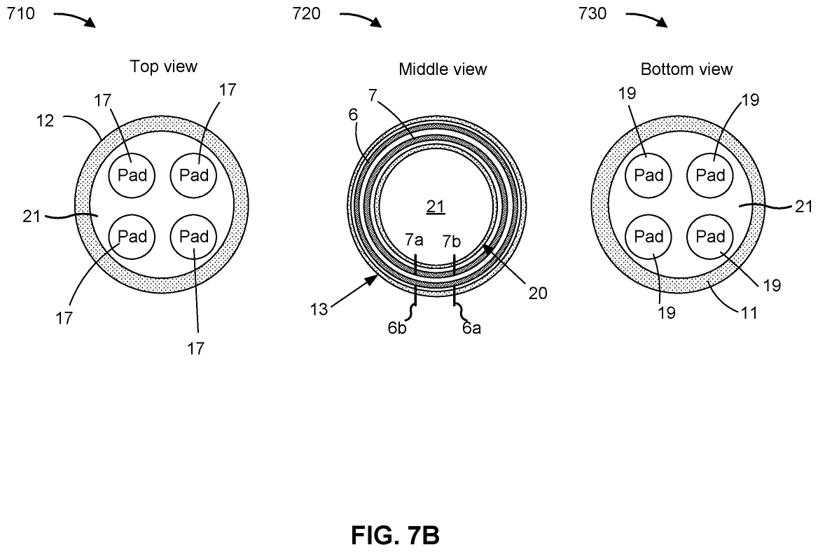

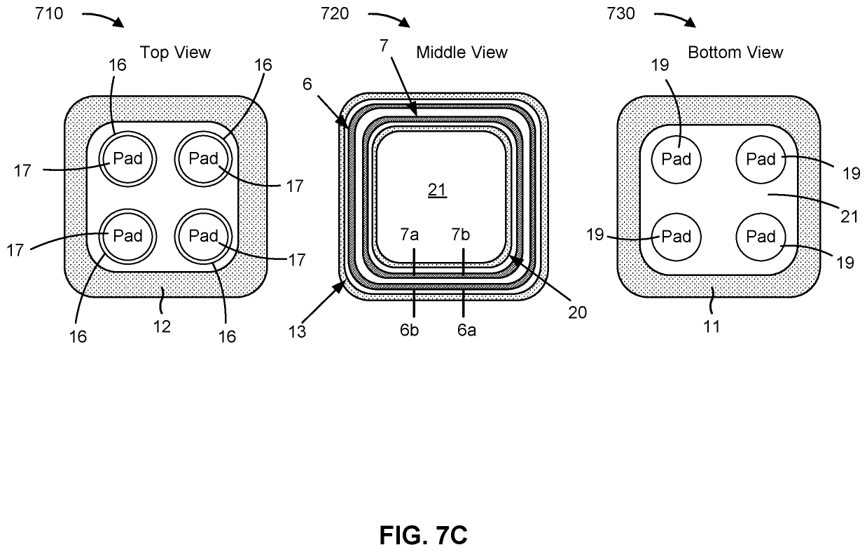

FIG. 7A illustrates a cross-sectional view of a multi-voltage domain device 700 according to one or more implementations. The multi-voltage domain device 600 is similar to the multi-voltage domain device 200 described in connection with FIGS. 2A and 2B, with the exception that the field concentrating structure 10 includes two magnetic ring structures that are laterally separated from each other. The two magnetic ring structures may include the magnetic ring structure 13, as described above in connection with FIGS. 2A and 2B, and another magnetic ring structure 20. The magnetic ring structure 13 may be arranged over the voltage domain A and the magnetic ring structure 20 may be arranged over the voltage domain B. Moreover, the two magnetic ring structures 13 and 20 may be concentric rings that are also concentric with the first coil 6 and the second coil 7. Thus, the magnetic ring structure 13 may surround the first coil 6, the second coil 7, and the magnetic ring structure 20. Moreover, the magnetic ring structure 20 may be surrounded by the first coil 6, the second coil 7, and the magnetic ring structure 13. The magnetic ring structure 20 may form an internal volume 21 that may be used for providing conductive interconnects for providing electrical connections to one or more components.

In addition, the top magnetic structure 12 may extend laterally between the magnetic ring structure 13 and the magnetic ring structure 20. For example, the top magnetic structure 12 may be mechanically coupled to a first upper portion of the magnetic ring structure 13 and to a second upper portion of the magnetic ring structure 20 such that the top magnetic structure 12 is arranged over the first coil 6 and the second coil 7. The bottom magnetic structure 11 may extend laterally between the magnetic ring structure 13 and the magnetic ring structure 20. For example, the bottom magnetic structure 11 may be coupled to a first lower portion of the magnetic ring structure 13 and to a second lower portion of the magnetic ring structure 20 such that the bottom magnetic structure 11 is arranged below the first coil 6 and the second coil 7.

As indicated above, FIG. 7A is provided as an example. Other examples may differ from what is described with regard to FIG. 7A.

FIG. 7B illustrates a top plan view 710, a middle plan view 720, and a bottom plan view 730 of the multi-voltage domain device 700 according to one or more implementations. The top plan view 710 is taken through a top portion of the field concentrating structure 10, through the top magnetic structure 12 along the x-axis. The middle plan view 720 is taken through a middle portion of the field concentrating structure 10, through the magnetic ring structure 13 along the x-axis. The bottom plan view 730 is taken through a bottom portion of the field concentrating structure 10, through the bottom magnetic structure 11 along the x-axis.

As shown in the top plan view 710, the top magnetic structure 12 may have a hollow ring shape having an outer diameter that may be matched with a shape of the magnetic ring structure 13 and an inner diameter that may be matched with a shape of the magnetic ring structure 20.

In some implementations, the plurality of contact pads 17 may be arranged in the internal volume 21 defined by the top magnetic structure 12. Each of the terminals 6a and 6b of the first coil 6 and the terminals 7a and 7b of the second coil 7 may be electrically coupled to the first circuitry or to the second circuitry by a respective contact pad of the plurality of contact pads 17. Alternatively, the plurality of contact pads 19 may be arranged in the internal volume 21 defined by the bottom magnetic structure 11. Each of the terminals 6a and 6b of the first coil 6 and the terminals 7a and 7b of the second coil 7 may be electrically coupled to the first circuitry or to the second circuitry by a respective contact pad of the plurality of contact pads 19.

As shown in the middle plan view 720, the magnetic ring structures 13 and 20 may be concentric with the first coil 6 and the second coil 7. In addition, the terminals 6a and 6b of the first coil 6 may extend through holes formed in the magnetic ring structure 13, and the terminals 7a and 7b of the second coil 7 may extend through holes formed in the magnetic ring structure 20.

As indicated above, FIG. 7B is provided as an example. Other examples may differ from what is described with regard to FIG. 7B.

FIG. 7C illustrates the top plan view 710, the middle plan view 720, and the bottom plan view 730 of the multi-voltage domain device 700 according to one or more implementations. The multi-voltage domain device 700 shown in FIG. 7C is similar to the multi-voltage domain device 700 described in connection with FIG. 7B, with the exception that the first coil 6, the second coil 7, the bottom magnetic structure 11, the top magnetic structure 12, and the magnetic ring structure 13 have a rectangular shape.

As indicated above, FIG. 7C is provided as an example. Other examples may differ from what is described with regard to FIG. 7C.

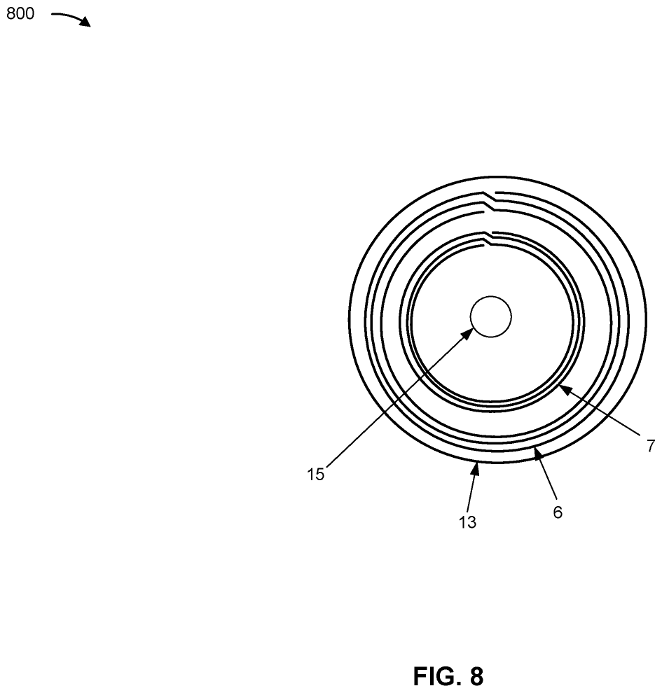

FIG. 8 illustrates a middle plan view of a multi-voltage domain device 800 according to one or more implementations. The multi-voltage domain device 800 includes the first coil 6, the second coil 7, the magnetic ring structure 13, and the magnetic column 15, as similarly described in connection with the middle plan view 220 of FIG. 2B. However, in this example, the first coil 6 and the second coil 7 may have spiral-shaped windings. In addition, the first coil 6, the second coil 7, and the magnetic ring structure 13 may have shapes other than circular. For example, the first coil 6, the second coil 7, and the magnetic ring structure 13 may have a quadrilateral shape, such as a rectangular shape.

As indicated above, FIG. 8 is provided as an example. Other examples may differ from what is described with regard to FIG. 8.

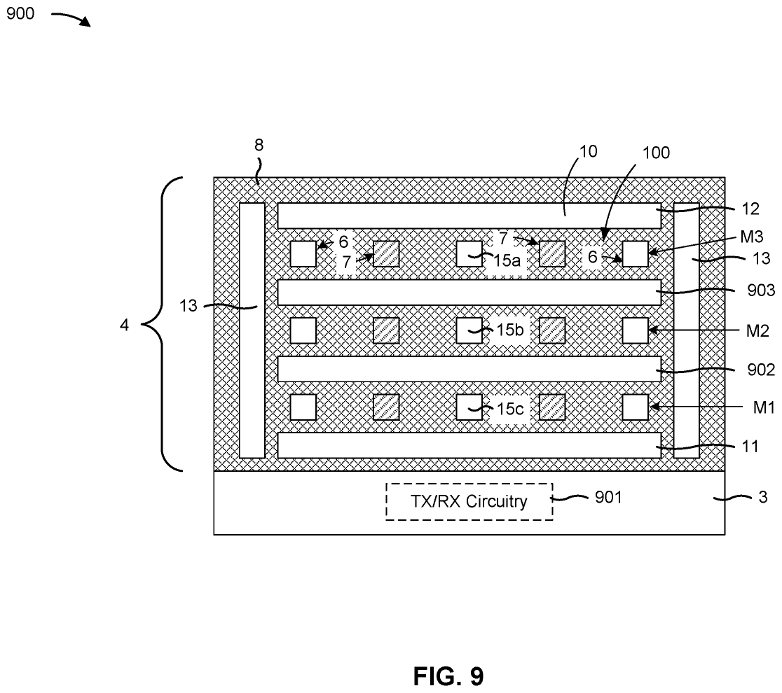

FIG. 9 illustrates a cross-sectional view of a multi-voltage domain device 900 according to one or more implementations. The multi-voltage domain device 900 may include the lateral transformer 100, including the first coil 6 and the second coil 7, as described in connection with FIG. 1.

FIG. 9 shows the multi-voltage domain device 900 with the circuit substrate 3 and a transmitter (TX)/receiver (RX) circuit 901 in the circuit substrate 3. The TX/RX circuit 901 may include any standard circuitry used to wirelessly transmit and receive power over a galvanic isolation barrier (e.g., isolation region 5). In some implementations, the TX/RX circuit 901 may include a transmitter circuit arranged in the voltage domain A of the circuit substrate 3 and a receiver circuit of the TX/RX circuit 901 arranged in the voltage domain B of the circuit substrate 3. In some implementations, the TX/RX circuit 901 may include two transceiver circuits for bidirectional energy transfer across the galvanic isolation barrier.

For wireless power transmission, the TX/RX circuit 901 may include one or more power transistors electrically connected to the first coil 6 of the lateral transformer 100, a respective gate driver for driving each power transistor, a microcontroller for controlling each gate driver, and a power supply for energizing the first coil 6 via the one or more power transistors. For wireless power reception, the TX/RX circuit 901 may include a synchronous bridge rectifier electrically connected to the second coil 7 of the lateral transformer 100, a gate driver for the synchronous bridge rectifier, and a microcontroller for controlling the gate driver. Power may be wirelessly transmitted across the lateral transformer 100, which provides galvanic isolation between the transmitter side and receiver side of the lateral transformer 100. The power transmission may be used for transmitting communications (e.g., control signals, configuration signals, and/or fault signals) or for transferring power from the transmitter side to the receiver side for providing power to one or more components located on the receiver side.

The layer stack 4 is formed on the circuit substrate 3 and may be similar to the layer stack 4 described in connection with FIG. 2A. Thus, the layer stack 4 may be comprised of multiple sub-insulator layers and metal layers. The metal layers may be used to form the first coil 6 and the second coil 7. In addition, the layer stack 4 may include magnetic layers formed therein. For example, the layer stack 4 may include a magnetic layer (e.g., a ferrite layer) that forms the bottom magnetic structure 11 and another magnetic layer that forms the top magnetic structure 12. Additionally, or alternatively, the layer stack 4 may include the magnetic ring structure 13. Additionally, or alternatively, the layer stack 4 may include one or more intermediate magnetic layers arranged in the layer stack 4 between the windings of the first coil 6 and between the windings of the second coil 7. For example, the layer stack 4 may include a first intermediate magnetic layer 902 arranged vertically between metal layers M1 and M2 of the first coil 6 and the second coil 7, and a second intermediate magnetic layer 903 arranged vertically between metal layers M2 and M3 of the first coil 6 and the second coil 7. The first intermediate magnetic layer 902 and the second intermediate magnetic layer 903 may be part of the field concentrating structure 10. Additionally, or alternatively, the layer stack 4 may include one or more magnetic columns 15a, 15b, or 15c that are arranged vertically between two horizontal magnetic layers, such as the bottom magnetic structure 11, the top magnetic structure 12, the first intermediate magnetic layer 902, and the second intermediate magnetic layer 903.

As indicated above, FIG. 9 is provided as an example. Other examples may differ from what is described with regard to FIG. 9.

The following provides an overview of some Aspects of the present disclosure:

Aspect 1: A multi-voltage domain device, comprising: a circuit substrate comprising a first main surface and a second main surface arranged opposite to the first main surface, wherein the circuit substrate comprises: a first region comprising first circuitry that operates in a first voltage domain, a second region comprising second circuitry that operates in a second voltage domain, and an isolation region that electrically isolates the first region and the second region in a lateral direction that extends parallel to the first and the second main surfaces; a layer stack arranged on the first main surface of the circuit substrate, the layer stack comprising a plurality of sub-insulator layers that form a stack insulator layer, a first coil arranged in the stack insulator layer, and a second coil arranged in the stack insulator layer and laterally separated from the first coil in the lateral direction by the stack insulator layer, wherein the first coil and the second coil are magnetically coupled to each other in the lateral direction, wherein the first coil is electrically coupled to the first circuitry and is isolated from the second region, and wherein the second coil is electrically coupled to the second circuitry and is isolated from the first region; and a field concentrating structure arranged on the first main surface, wherein the field concentrating structure is configured to attract a first magnetic field produced by the first coil such that the first magnetic field is concentrated about the first coil, and attract a second magnetic field produced by the second coil such that the second magnetic field is concentrated about the second coil.

Aspect 2: The multi-voltage domain device of Aspect 1, wherein the isolation region comprises one or more trench isolation barriers, each of which extends vertically from the first main surface to the second main surface.

Aspect 3: The multi-voltage domain device of Aspects 1-2, wherein the first region surrounds the second region, and the first coil surrounds the second coil.

Aspect 4: The multi-voltage domain device of Aspects 1-3, wherein the field concentrating structure is configured to guide the first magnetic field along a first magnetic field path, including through the field concentrating structure, and to guide the second magnetic field along a second magnetic field path, including through the field concentrating structure.

Aspect 5: The multi-voltage domain device of Aspects 1-4, wherein the field concentrating structure is electrically isolated from the first coil and the second coil by the stack insulator layer.

Aspect 6: The multi-voltage domain device of Aspects 1-5, wherein the field concentrating structure is configured to increase an energy transfer between the first coil and the second coil.

Aspect 7: The multi-voltage domain device of Aspects 1-6, wherein the field concentrating structure is configured to encapsulate the first coil and the second coil.

Aspect 8: The multi-voltage domain device of Aspect 7, wherein the field concentrating structure includes a plurality of openings, wherein the first coil comprises two first terminals that are electrically coupled to the first circuitry through first respective openings of the plurality of openings, and wherein the second coil comprises two second terminals that are electrically coupled to the second circuitry through second respective openings of the plurality of openings.

Aspect 9: The multi-voltage domain device of Aspect 8, further comprising: a plurality of contact pads respectively arranged in the plurality of openings, wherein each of the two first terminals and the two second terminals is electrically coupled to the first circuitry or to the second circuitry by a respective contact pad of the plurality of contact pads.

Aspect 10: The multi-voltage domain device of Aspect 7, wherein the field concentrating structure comprises: a bottom magnetic structure arranged below the first coil and the second coil; a top magnetic structure arranged over the first coil and the second coil; and a magnetic ring structure that surrounds the first coil and the second coil, wherein the magnetic ring structure extends vertically between the bottom magnetic structure and the top magnetic structure to define an internal volume in which the first coil and the second coil are arranged.

Aspect 11: The multi-voltage domain device of Aspect 10, wherein the field concentrating structure comprises: a magnetic column that is arranged over the second region and extends vertically between the bottom magnetic structure and the top magnetic structure, wherein the magnetic column is encircled by the first coil and the second coil.

Aspect 12: The multi-voltage domain device of Aspect 7, wherein the field concentrating structure is integrated within the layer stack.

Aspect 13: The multi-voltage domain device of Aspects 1-12, wherein the field concentrating structure is at least partially arranged in the stack insulator layer.

Aspect 14: The multi-voltage domain device of Aspects 1-13, wherein the first region surrounds the second region, and the first coil surrounds the second coil, wherein the field concentrating structure comprises: a bottom magnetic layer that extends laterally between a first lateral side of the first coil and a second lateral side of the first coil that is arranged opposite to the first lateral side, wherein the bottom magnetic layer is arranged below the first coil and the second coil; and a top magnetic layer that extends laterally between the first lateral side of the first coil and the second lateral side of the first coil, wherein the top magnetic layer extends over the first coil and the second coil.

Aspect 15: The multi-voltage domain device of Aspect 14, wherein the field concentrating structure comprises: a magnetic ring structure that encircles the first coil and the second coil, wherein the magnetic ring structure extends vertically between the bottom magnetic layer and the top magnetic layer to define an internal volume in which the first coil and the second coil are arranged.

Aspect 16: The multi-voltage domain device of Aspect 14, wherein the field concentrating structure comprises: a magnetic column that is arranged over the second region and extends vertically between the bottom magnetic layer and the top magnetic layer, wherein the magnetic column is surrounded by the first coil and the second coil.

Aspect 17: The multi-voltage domain device of Aspect 14, wherein the field concentrating structure includes a plurality of openings, wherein the first coil comprises two first terminals that are electrically coupled to the first circuitry through first respective openings of the plurality of openings, and wherein the second coil comprises two second terminals that are electrically coupled to the second circuitry through second respective openings of the plurality of openings.

Aspect 18: The multi-voltage domain device of Aspects 1-17, wherein the field concentrating structure comprises: a magnetic ring structure that encircles the first coil and the second coil, wherein the magnetic ring structure extends vertically to define an internal volume in which the first coil and the second coil are at least partially arranged.

Aspect 19: The multi-voltage domain device of Aspect 18, wherein the field concentrating structure comprises: a magnetic column embedded in the layer stack, wherein the magnetic column is arranged over the second region and extends vertically within the layer stack, and wherein the magnetic column is encircled by the first coil and the second coil.

Aspect 20: The multi-voltage domain device of Aspect 18, wherein the magnetic ring structure is part of the layer stack.

Aspect 21: The multi-voltage domain device of Aspect 18, wherein the magnetic ring structure is a first magnetic ring structure that defines a first internal volume in which the first coil and the second coil are arranged, wherein the field concentrating structure comprises: a second magnetic ring structure that encircles the first coil and the second coil, wherein the second magnetic ring structure extends vertically to define a second internal volume in which the first coil and the second coil are arranged, wherein the first magnetic ring structure is arranged in a first sub-stack of the layer stack, wherein the second magnetic ring structure is arranged in a second sub-stack of the layer stack, and wherein the first magnetic ring structure and the second magnetic ring structure are separated by at least one sub-insulator layer in a vertical direction of the layer stack.

Aspect 22: The multi-voltage domain device of Aspect 18, wherein the magnetic ring structure includes at least one opening, wherein the first coil comprises two first terminals that are electrically coupled to the first circuitry through the at least one opening, and wherein the second coil comprises two second terminals that are electrically coupled to the second circuitry through the at least one opening.

Aspect 23: The multi-voltage domain device of Aspects 1-22, wherein the field concentrating structure comprises: a magnetic column arranged in the stack insulator layer, wherein the magnetic column is arranged over the second region and extends vertically within the layer stack, and wherein the magnetic column is encircled by the first coil and the second coil.

Aspect 24: The multi-voltage domain device of Aspects 1-23, wherein the field concentrating structure comprises: a first magnetic column arranged in the stack insulator layer, wherein the first magnetic column is arranged over the second region and extends vertically within the layer stack, and wherein the first magnetic column is surrounded by the first coil and the second coil, and a second magnetic column arranged in the stack insulator layer, wherein the second magnetic column is arranged over the second region and extends vertically within the layer stack, and wherein the second magnetic column is surrounded by the first coil and the second coil, wherein the first magnetic column is arranged in a first sub-stack of the layer stack, wherein the second magnetic column is arranged in a second sub-stack of the layer stack, and wherein the first magnetic column and the second magnetic column are separated by at least one sub-insulator layer in a vertical direction of the layer stack.

Aspect 25: The multi-voltage domain device of Aspects 1-24, wherein the field concentrating structure comprises: a first magnetic ring structure that is arranged vertically over the second region and is surrounded by the first coil and the second coil; and a second magnetic ring structure that is arranged vertically over the first region and surrounds the first coil, the second coil, and the first magnetic ring structure.

Aspect 26: The multi-voltage domain device of Aspect 25, wherein the field concentrating structure comprises: a top magnetic layer that extends laterally between the first magnetic ring structure and the second magnetic ring structure, wherein the top magnetic layer is coupled to a first upper portion of the first magnetic ring structure and to a second upper portion of the second magnetic ring structure, and wherein the top magnetic layer is arranged over the first coil and the second coil, and a bottom magnetic layer that extends laterally between the first magnetic ring structure and the second magnetic ring structure, wherein the bottom magnetic layer is coupled to a first lower portion of the first magnetic ring structure and to a second lower portion of the second magnetic ring structure, and wherein the bottom magnetic layer is arranged below the first coil and the second coil.

27. The multi-voltage domain device of Aspects 1-26, wherein the field concentrating structure comprises: an intermediate magnetic layer arranged in the layer stack between windings of the first coil and between windings of the second coil.

The foregoing disclosure provides illustration and description, but is not intended to be exhaustive or to limit the implementations to the precise form disclosed. Modifications and variations are possible in light of the above disclosure or may be acquired from practice of the implementations.

As used herein, the term component is intended to be broadly construed as hardware, firmware, or a combination of hardware and software. It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code—it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein refers to any of the foregoing structures or any other structure suitable for implementation of the techniques described herein. Software may be stored on a non-transitory computer-readable medium such that the non-transitory computer readable medium includes a program code or a program algorithm stored thereon which, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal further information. Signal conditioning, as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation and any other processes required to make a signal suitable for processing after conditioning.

Some implementations may be described herein in connection with thresholds. As used herein, satisfying a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A multi-voltage domain device, comprising:
a circuit substrate comprising a first main surface and a second main surface arranged opposite to the first main surface, wherein the circuit substrate comprises:
a first region comprising first circuitry that operates in a first voltage domain,
a second region comprising second circuitry that operates in a second voltage domain, and
an isolation region that electrically isolates the first region and the second region in a lateral direction that extends parallel to the first and the second main surfaces;
a layer stack arranged on the first main surface of the circuit substrate, the layer stack comprising a plurality of sub-insulator layers that form a stack insulator layer, a first coil arranged in the stack insulator layer, and a second coil arranged in the stack insulator layer and laterally separated from the first coil in the lateral direction by the stack insulator layer,
wherein the first coil and the second coil are magnetically coupled to each other in the lateral direction,
wherein the first coil is electrically coupled to the first circuitry and is isolated from the second region, and
wherein the second coil is electrically coupled to the second circuitry and is isolated from the first region; and
a field concentrating structure arranged on the first main surface, wherein the field concentrating structure is configured to attract a first magnetic field produced by the first coil such that the first magnetic field is concentrated about the first coil, and attract a second magnetic field produced by the second coil such that the second magnetic field is concentrated about the second coil.

2. The multi-voltage domain device of claim 1, wherein the isolation region comprises one or more trench isolation barriers, each of which extends vertically from the first main surface to the second main surface.

3. The multi-voltage domain device of claim 1, wherein the first region surrounds the second region, and the first coil surrounds the second coil.

4. The multi-voltage domain device of claim 1, wherein the field concentrating structure is configured to guide the first magnetic field along a first magnetic field path, including through the field concentrating structure, and to guide the second magnetic field along a second magnetic field path, including through the field concentrating structure.

5. The multi-voltage domain device of claim 1, wherein the field concentrating structure is electrically isolated from the first coil and the second coil by the stack insulator layer.

6. The multi-voltage domain device of claim 1, wherein the field concentrating structure is configured to increase an energy transfer between the first coil and the second coil.

7. The multi-voltage domain device of claim 1, wherein the field concentrating structure is configured to encapsulate the first coil and the second coil.

8. The multi-voltage domain device of claim 7, wherein the field concentrating structure includes a plurality of openings,
wherein the first coil comprises two first terminals that are electrically coupled to the first circuitry through first respective openings of the plurality of openings, and
wherein the second coil comprises two second terminals that are electrically coupled to the second circuitry through second respective openings of the plurality of openings.

9. The multi-voltage domain device of claim 8, further comprising:
a plurality of contact pads respectively arranged in the plurality of openings,
wherein each of the two first terminals and the two second terminals is electrically coupled to the first circuitry or to the second circuitry by a respective contact pad of the plurality of contact pads.

10. The multi-voltage domain device of claim 7, wherein the field concentrating structure comprises:
a bottom magnetic structure arranged below the first coil and the second coil;
a top magnetic structure arranged over the first coil and the second coil; and
a magnetic ring structure that surrounds the first coil and the second coil, wherein the magnetic ring structure extends vertically between the bottom magnetic structure and the top magnetic structure to define an internal volume in which the first coil and the second coil are arranged.

11. The multi-voltage domain device of claim 10, wherein the field concentrating structure comprises:
a magnetic column that is arranged over the second region and extends vertically between the bottom magnetic structure and the top magnetic structure, wherein the magnetic column is encircled by the first coil and the second coil.

12. The multi-voltage domain device of claim 7, wherein the field concentrating structure is integrated within the layer stack.

13. The multi-voltage domain device of claim 1, wherein the field concentrating structure is at least partially arranged in the stack insulator layer.

14. The multi-voltage domain device of claim 1, wherein the first region surrounds the second region, and the first coil surrounds the second coil,
wherein the field concentrating structure comprises:
a bottom magnetic layer that extends laterally between a first lateral side of the first coil and a second lateral side of the first coil that is arranged opposite to the first lateral side, wherein the bottom magnetic layer is arranged below the first coil and the second coil; and
a top magnetic layer that extends laterally between the first lateral side of the first coil and the second lateral side of the first coil, wherein the top magnetic layer extends over the first coil and the second coil.

15. The multi-voltage domain device of claim 14, wherein the field concentrating structure comprises:
a magnetic ring structure that encircles the first coil and the second coil, wherein the magnetic ring structure extends vertically between the bottom magnetic layer and the top magnetic layer to define an internal volume in which the first coil and the second coil are arranged.

16. The multi-voltage domain device of claim 14, wherein the field concentrating structure comprises:
a magnetic column that is arranged over the second region and extends vertically between the bottom magnetic layer and the top magnetic layer, wherein the magnetic column is surrounded by the first coil and the second coil.

17. The multi-voltage domain device of claim 14, wherein the field concentrating structure includes a plurality of openings,
wherein the first coil comprises two first terminals that are electrically coupled to the first circuitry through first respective openings of the plurality of openings, and
wherein the second coil comprises two second terminals that are electrically coupled to the second circuitry through second respective openings of the plurality of openings.

18. The multi-voltage domain device of claim 1, wherein the field concentrating structure comprises:
a magnetic ring structure that encircles the first coil and the second coil, wherein the magnetic ring structure extends vertically to define an internal volume in which the first coil and the second coil are at least partially arranged.

19. The multi-voltage domain device of claim 18, wherein the field concentrating structure comprises:
a magnetic column embedded in the layer stack, wherein the magnetic column is arranged over the second region and extends vertically within the layer stack, and wherein the magnetic column is encircled by the first coil and the second coil.

20. The multi-voltage domain device of claim 18, wherein the magnetic ring structure is part of the layer stack.

21. The multi-voltage domain device of claim 18, wherein the magnetic ring structure is a first magnetic ring structure that defines a first internal volume in which the first coil and the second coil are arranged,
wherein the field concentrating structure comprises:
a second magnetic ring structure that encircles the first coil and the second coil, wherein the second magnetic ring structure extends vertically to define a second internal volume in which the first coil and the second coil are arranged,
wherein the first magnetic ring structure is arranged in a first sub-stack of the layer stack,
wherein the second magnetic ring structure is arranged in a second sub-stack of the layer stack, and
wherein the first magnetic ring structure and the second magnetic ring structure are separated by at least one sub-insulator layer in a vertical direction of the layer stack.

22. The multi-voltage domain device of claim 18, wherein the magnetic ring structure includes at least one opening,
wherein the first coil comprises two first terminals that are electrically coupled to the first circuitry through the at least one opening, and
wherein the second coil comprises two second terminals that are electrically coupled to the second circuitry through the at least one opening.

23. The multi-voltage domain device of claim 1, wherein the field concentrating structure comprises:
a magnetic column arranged in the stack insulator layer, wherein the magnetic column is arranged over the second region and extends vertically within the layer stack, and wherein the magnetic column is encircled by the first coil and the second coil.

24. The multi-voltage domain device of claim 1, wherein the field concentrating structure comprises:
a first magnetic column arranged in the stack insulator layer, wherein the first magnetic column is arranged over the second region and extends vertically within the layer stack, and wherein the first magnetic column is surrounded by the first coil and the second coil; and
a second magnetic column arranged in the stack insulator layer, wherein the second magnetic column is arranged over the second region and extends vertically within the layer stack, and wherein the second magnetic column is surrounded by the first coil and the second coil,
wherein the first magnetic column is arranged in a first sub-stack of the layer stack,
wherein the second magnetic column is arranged in a second sub-stack of the layer stack, and
wherein the first magnetic column and the second magnetic column are separated by at least one sub-insulator layer in a vertical direction of the layer stack.

25. The multi-voltage domain device of claim 1, wherein the field concentrating structure comprises:
a first magnetic ring structure that is arranged vertically over the second region and is surrounded by the first coil and the second coil; and
a second magnetic ring structure that is arranged vertically over the first region and surrounds the first coil, the second coil, and the first magnetic ring structure.

26. The multi-voltage domain device of claim 25, wherein the field concentrating structure comprises:
a top magnetic layer that extends laterally between the first magnetic ring structure and the second magnetic ring structure, wherein the top magnetic layer is coupled to a first upper portion of the first magnetic ring structure and to a second upper portion of the second magnetic ring structure, and wherein the top magnetic layer is arranged over the first coil and the second coil, and
a bottom magnetic layer that extends laterally between the first magnetic ring structure and the second magnetic ring structure, wherein the bottom magnetic layer is coupled to a first lower portion of the first magnetic ring structure and to a second lower portion of the second magnetic ring structure, and wherein the bottom magnetic layer is arranged below the first coil and the second coil.

27. The multi-voltage domain device of claim 1, wherein the field concentrating structure comprises:
an intermediate magnetic layer arranged in the layer stack between windings of the first coil and between windings of the second coil.

28. A multi-voltage domain device, comprising:
a layer stack comprising a plurality of insulator layers and a plurality of conductive layers, a first coil arranged in the layer stack, and a second coil arranged in the layer stack and laterally isolated from the first coil in a lateral direction by insulator material of the layer stack,
wherein the first coil and the second coil are magnetically coupled to each other in the lateral direction,
wherein the first coil is associated with a first voltage domain and is isolated from a second voltage domain, and
wherein the second coil is associated with the second voltage domain and is isolated from the first voltage domain; and
a field concentrating structure integrated at least partially in the layer stack, wherein the field concentrating structure is configured to attract a first magnetic field produced by the first coil such that the first magnetic field is concentrated about the first coil, and attract a second magnetic field produced by the second coil such that the second magnetic field is concentrated about the second coil.

29. The multi-voltage domain device of claim 28, wherein the layer stack is a first layer stack,
wherein the multi-voltage domain device further comprises:
a second layer stack of sub-insulator layers and conductive layers, wherein the second layer stack is coupled to the first layer stack and comprises:
a first region comprising first circuitry that operates in a first voltage domain,
a second region comprising second circuitry that operates in a second voltage domain, and
an isolation region that electrically isolates the first region and the second region in the lateral direction.
